(19) United States
(12) Patent Application Publication
(10) Pub. No.: US 2025/0167135 A1
(43) Pub. Date: May 22, 2025

(54) SEMICONDUCTOR PACKAGE INCLUDING A STIFFENER

(71) Applicant: SAMSUNG ELECTRONICS CO., LTD., SUWON-SI (KR)

(72) Inventors: Jongkook Kim, Suwon-si (KR); Heungkyu Kwon, Suwon-si (KR); Junghwan Jang, Singapore (SG); Youngcheol Kim, Singapore (SG); Choonheung Lee, Singapore (SG); Minki Ahn, Suwon-si (KR); Jaegwon Jang, Suwon-si (KR); Hangchul Choi, Singapore (SG); Heejung Choi, Suwon-si (KR)

(73) Assignee: STATS ChipPAC Pte. Ltd., Singapore (SG)

(21) Appl. No.: 18/749,785

(22) Filed: Jun. 21, 2024

(30) Foreign Application Priority Data
Nov. 16, 2023 (SG) 10202303246V

(51) Int. Cl. H01L 23/00; H01L 23/31; H01L 23/36; H01L 23/49; H01L 23/498; H01L 23/538; H01L 25/16

(52) U.S. Cl. CPC H01L 23/562; H01L 23/3107; H01L 23/36; H01L 23/49; H01L 23/5385; H01L 25/16; H01L 23/49816; H01L 24/16; H01L 2224/16225; H01L 2924/19105

(57) ABSTRACT

A semiconductor package including a first redistribution structure, a second redistribution structure disposed on the first redistribution structure, a semiconductor chip disposed on an upper surface of the second redistribution structure, a bridge chip disposed on a lower surface of the second redistribution structure, a molding layer disposed between the first redistribution structure and the second redistribution structure, where the molding layer surrounds the bridge chip, and a stiffener disposed on the upper surface of the second redistribution structure. The stiffener includes an opening. The semiconductor chip is disposed in the opening of the stiffener.

### CROSS-REFERENCE TO RELATED APPLICATION

This U.S. non-provisional patent application claims priority under 35 U.S.C. § 119 to Singapore Patent Application No. 10202303246V, filed on Nov. 16, 2023, in the Intellectual Property Office of Singapore (IPOS), the disclosure of which is incorporated by reference herein in its entirety.

### BACKGROUND

The inventive concept relates to a semiconductor package. More particularly, the inventive concept relates to a semiconductor package including a stiffener.

Semiconductor packages are implemented from semiconductor chips for use in electronic products. In semiconductor packages, semiconductor chips are mounted on a printed circuit board and electrically connected to the printed circuit board using bonding wires or bounding bumps. With advancement in semiconductor packages leading to higher performance, the size of the semiconductor packages have increased. Accordingly, a semiconductor package including a stiffener is used to control warpage occurred due to differences in thermal expansion coefficients of one or more components in the semiconductor package.

### SUMMARY

A semiconductor package including a first redistribution structure, a second redistribution structure disposed on the first redistribution structure, a semiconductor chip disposed on an upper surface of the second redistribution structure, a bridge chip disposed on a lower surface of the second redistribution structure, a molding layer disposed between the first redistribution structure and the second redistribution structure, wherein the molding layer surrounds the bridge chip; and a stiffener disposed on the upper surface of the second redistribution structure. In one aspect, the stiffener includes an opening. In one aspect, the semiconductor chip is disposed in the opening of the stiffener.

A semiconductor package including a first redistribution structure, a second redistribution structure disposed on the first redistribution structure, a semiconductor chip disposed on an upper surface of the second redistribution structure, a bridge chip disposed on a lower surface of the second redistribution structure, a passive device disposed on the lower surface of the second redistribution structure and spaced apart from the bridge chip in a horizontal direction. In one aspect, the horizontal direction is parallel to the upper surface of the second redistribution structure. The semiconductor package further includes a molding layer disposed between the first redistribution structure and the second redistribution structure, where the molding layer surrounds the bridge chip and the passive device, a conductive post spaced apart from the bridge chip and the passive device in the horizontal direction within the molding layer, a heat sink disposed on an upper surface of the semiconductor chip, and a stiffener disposed on the upper surface of the second redistribution structure, where the stiffener comprises an opening. In one aspect, the semiconductor chip is disposed in the opening of the stiffener.

A semiconductor package including a first redistribution structure that includes a passivation layer, an under bump metallurgy (UBM) layer disposed on and covering a portion of a lower surface of the passivation layer, and a conductive layer in contact with the UBM layer and exposed at an upper surface of the passivation layer. The semiconductor package further includes a second redistribution structure disposed on the first redistribution structure, where the second redistribution structure includes one or more redistribution insulating layers, one or more conductive line patterns disposed in the one or more redistribution insulating layers and extending in a horizontal direction, and one or more conductive vias disposed in the one or more redistribution insulating layers and extending in a vertical direction perpendicular to the horizontal direction, where the horizontal direction is parallel to an upper surface of the second redistribution structure. The semiconductor package further includes one or more semiconductor chips disposed on the upper surface of the second redistribution structure, a bridge chip disposed on a lower surface of the second redistribution structure, where the bridge chip provides an electrical connection path among the one or more semiconductor chips, a passive device disposed on the lower surface of the second redistribution structure and spaced apart from the bridge chip in the horizontal direction, a molding layer disposed between the first redistribution structure and the second redistribution structure, where the molding layer surrounds lower surfaces and side surfaces of the bridge chip and the passive device, a conductive post spaced apart from the bridge chip and the passive device in the horizontal direction within the molding layer, and a stiffener disposed on the upper surface of the second redistribution structure, where the stiffener includes an opening. The one or more semiconductor chips are disposed in the opening of the stiffener.

### BRIEF DESCRIPTION OF THE DRAWINGS

FIG. 1A is an example of a horizontal cross-sectional view of the shape of a stiffener according to an embodiment of the present inventive concept.

FIGS. 1B and 1C are examples of vertical cross-sectional views taken along line A-A′ in FIG. 1A.

FIG. 2A is an example of a horizontal cross-sectional view of the shape of a stiffener according to an embodiment of the present inventive concept.

FIG. 2B is an example of a vertical cross-sectional view taken along line B-B′ in FIG. 2A.

FIG. 3A is an example of a plan view of a semiconductor package according to an embodiment of the present inventive concept.

FIG. 3B is an example of a cross-sectional view taken along line C-C′ in FIG. 3A.

FIG. 4 is an example of a cross-sectional view of a semiconductor package according to according to an embodiment of the present inventive concept.

FIG. 5 is an example of a cross-sectional view of a semiconductor package according to according to an embodiment of the present inventive concept.

FIG. 6 is an example of a cross-sectional view of a semiconductor package according to according to an embodiment of the present inventive concept.

FIG. 7 is an example of a cross-sectional view of a semiconductor package according to according to an embodiment of the present inventive concept.

FIG. 8 is an example of a plane view of a semiconductor package according to an embodiment of the present inventive concept.

FIGS. 9A, 9B, 9C, 9D, 9E, 9F, 9G, and 9H are examples of cross-sectional views of a method for manufacturing a semiconductor package according to an embodiment of the present inventive concept.

### DETAILED DESCRIPTION OF THE EMBODIMENTS

Hereinafter, embodiments of the present inventive concept are described in detail with reference to the drawings. In some cases, the same reference numerals are used for the same components in the drawings. In some cases, redundant descriptions thereof may be omitted.

In some cases, the embodiments of the present inventive concept may be modified in various ways. In some cases, the present inventive concept include various embodiments. In some cases, specific embodiments are illustrated in the drawings and described in detail in the detailed description. However, this is not intended to limit the scope to a specific embodiment, and should be understood to include all modifications, equivalents, and substitutes included in the disclosed spirit and technical scope. In describing the embodiments, when it is determined that detailed description of related known technologies may obscure the gist, the detailed description thereof are omitted.

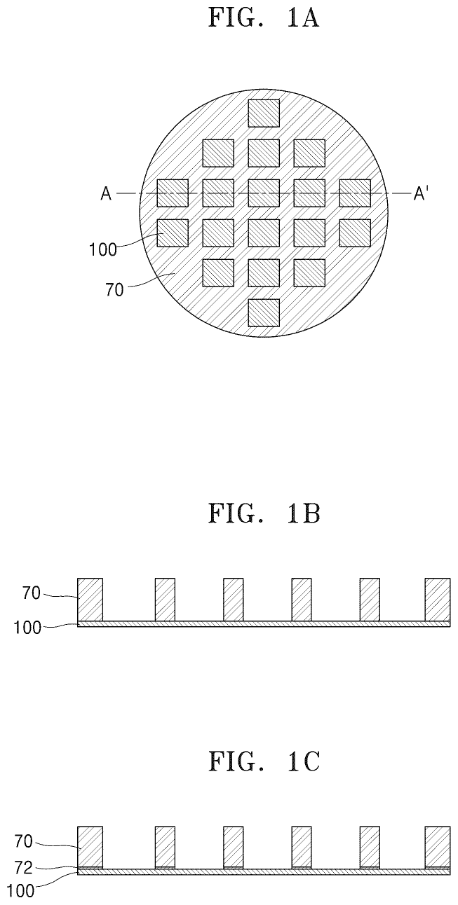

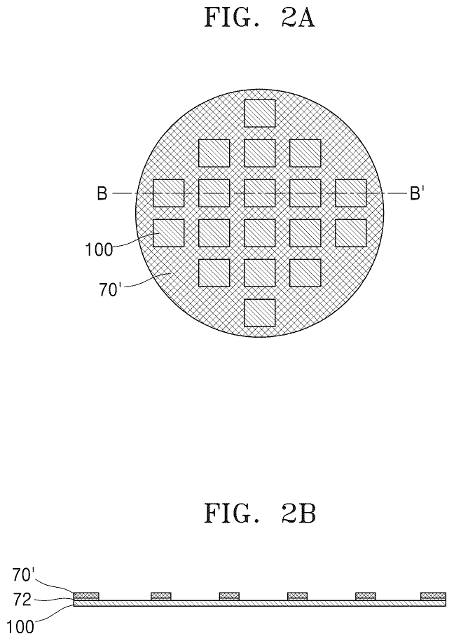

FIG. 1A is an example of a horizontal cross-sectional view of the shape of a stiffener according to an embodiment of the present inventive concept. FIGS. 1B and 1C are examples of vertical cross-sectional views taken along line A-A′ in FIG. 1A. FIG. 2A is an example of a horizontal cross-sectional view of the shape of a stiffener according to an embodiment of the present inventive concept. FIG. 2B is an example of a vertical cross-sectional view taken along line B-B′ in FIG. 2A.

Referring to FIGS. 1A to 1C, the stiffener 70 may have a disk shape including a plurality of openings, where each of the plurality of openings includes a quadrangular shape in the horizontal cross-section view. In some cases, the stiffener 70 has a grid shape. The stiffener 70 may include a mold material. For example, the mold material may include thermoset, thermoplastic, UV-curable resin, or a combination thereof. For example, the mold material may include epoxy resin, silicone resin, or a combination thereof. For example, the mold material may include an epoxy mold compound (EMC). As shown in FIG. 1B, the stiffener 70 may be disposed on a first redistribution structure 100. As shown in FIG. 1C, the stiffener 70 may be disposed on the first redistribution structure 100 and an adhesive layer 72. For example, the adhesive layer 72 is disposed between the stiffener 70 and the first redistribution structure 100.

Referring to FIGS. 2A and 2B, the stiffener 70′ may include a metal material. The stiffener 70′ may be pre-manufactured based on a method such as die casting, injection, or forging. In some cases, the stiffener 70′ is attached to the first redistribution structure 100 using the adhesive layer 72. For example, the adhesive layer 72 is disposed between the stiffener 70′ and the first redistribution structure 100. As described below, one or more semiconductor chips may be disposed in the openings of the stiffeners 70 and 70′.

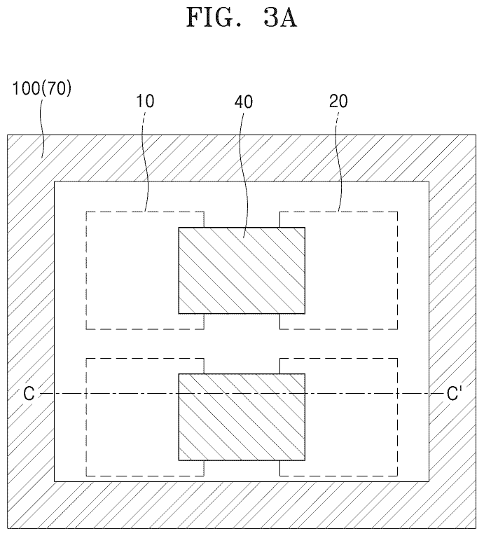

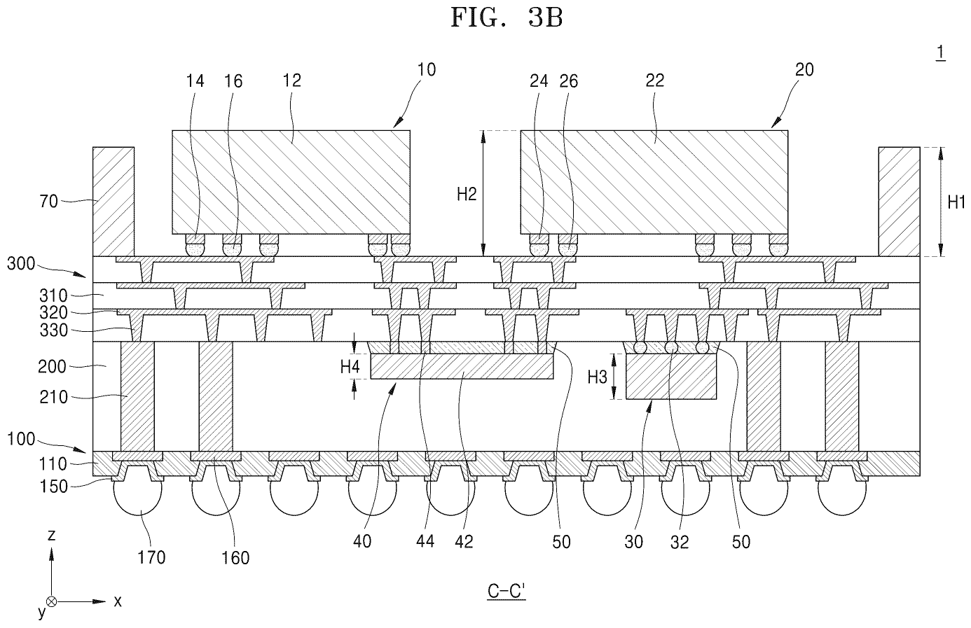

FIG. 3A is an example of a plan view of a semiconductor package according to according to an embodiment. FIG. 3B is an example of a cross-sectional view taken along line C-C′ in FIG. 3A. For the convenience of describing the embodiments depicted in the drawing, FIG. 3A shows a first semiconductor chip 10, a second semiconductor chip 20, a bridge chip 40, the first redistribution structure 100, and the stiffener 70.

Referring to FIGS. 3A and 3B, the semiconductor package 1 may include the first semiconductor chip 10, the second semiconductor chip 20, a first device 30, the bridge chip 40, the first redistribution structure 100, a molding layer 200, a second redistribution structure 300, and the stiffener 70.

In some aspects, a direction parallel to an upper surface of the first redistribution structure 100 may be referred to as a horizontal direction (e.g., X direction and/or Y direction), and a direction perpendicular to the horizontal direction (e.g., X direction and/or Y direction) may be referred to as a vertical direction (e.g., Z direction). In some cases, the perpendicular direction (e.g., Z direction) is parallel to a side surface of the of the first redistribution structure 100.

In some aspects, among two surfaces spaced apart in the vertical direction (e.g., Z direction), the surface further away from an external connection terminal 170 may be referred to as an upper surface of a component, and the surface opposite to the upper surface may be referred to as a lower surface of the component.

In some embodiments, the first redistribution structure 100 may include a passivation layer 110, an under bump metallurgy (UBM) layer 150, and a conductive layer 160. For example, the passivation layer 110 may have a single-layer structure. In an embodiment, the passivation layer 110 may have a multi-layer structure. In some cases, the passivation layer 110 may completely cover lower surface and side surfaces of the conductive layer 160 and expose an upper surface of the conductive layer 160. For example, an upper surface of the passivation layer 110 may be substantially coplanar with an upper surface of the conductive layer 160. In some cases, a part of the lower surface of the passivation layer 110 may be covered by the UBM layer 150. For example, a lower portion (e.g., a UBM pad) of the UBM layer 150 may be disposed on a lower surface of the passivation layer 110. In some cases, for example, the passivation layer 110 may include silicon oxide, silicon nitride, phosphosilicate glass (PSG), borophosphosilicate glass (BPSG), fluorosilicate glass (FSG), or an insulating material including a combination thereof.

The UBM layer 150 may include a UBM pad disposed on the lower surface of the passivation layer 110. In some cases, a lower surface of the UBM pad may be at a lower level than a lower surface of passivation layer 110. In some cases, a lower surface of the UBM pad may be substantially coplanar with a lower surface of passivation layer 110. In some cases, the UMB layer 150 may include a UBM via vertically penetrating at least a portion of the passivation layer 110 and electrically connecting the UBM pad and the conductive layer 160. The UBM via may have a truncated cone cup shape with a partially empty center space. In an embodiment, the UBM via may have a truncated cone shape with a filled center space. The UBM pad may have a ring shape with an empty center space. In an embodiment, the UBM pad may have a coin shape with a filled center space.

The UBM layer 150 may electrically connect different components of the semiconductor package 1, such as the conductive layer 160 and the external connection terminal 170. In some cases, the UBM layer 150 may prevent the formation of cracks in the external connection terminal 170 due to thermal shock between the external connection terminal 170 and the first redistribution structure 100, thereby improving the reliability of the semiconductor package 1. In some cases, for example, the UBM layer 150 may include copper (Cu), aluminum (Al), silver (Ag), gold (Au), tungsten (W), titanium (Ti), or a conductive material including a combination thereof.

The conductive layer 160 may be disposed in the passivation layer 110, and an upper surface of the conductive layer 160 may be exposed to the upper surface of the passivation layer 110. The conductive layers 160 may be respectively disposed below a plurality of conductive posts 210, and upper surfaces of the conductive layer 160 may be connected to lower surfaces of the plurality of conductive posts 210. The conductive layers 160 may be conductive patterns spaced apart in the first horizontal direction (e.g., X direction) or the second horizontal direction (e.g., Y direction). For example, as shown in FIG. 3B, the conductive layers 160 are conductive patterns disposed at one vertical level. In an embodiment, the conductive layers 160 may be conductive patterns having a multi-layer structure disposed at different vertical levels within the passivation layer 110. The conductive layers 160 may electrically connect different components such as the plurality of conductive posts 210 and the UBM layers 150. In some cases, for example, the conductive layer 160 may include a metal such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium (Ga), ruthenium (Ru), or a combination thereof.

In some embodiments, the semiconductor package 1 may include the external connection terminal 170 disposed on the lower surface of the passivation layer 110. For example, the external connection terminal 170 may be disposed below the UBM layer 150. The external connection terminal 170 may be configured to electrically and physically connect the first redistribution structure 100 to an external device. In some cases, for example, the external connection terminal 170 may have a structure of a solder ball or a conductive bump. The external connection terminal 170 may be electrically connected to the UBM layer 150 of the first redistribution structure 100 and electrically connected to an external device such as a module substrate or system board. In some cases, a width, measured in the first horizontal direction (e.g., the X direction), of the external connection terminal 170 may be less than a width UBM pad of the UBM layer 150.

As shown in FIG. 3B, the external connection terminals 170 might not be directly contacted and connected to the plurality of conductive posts 210 surrounding the bridge chip 40. For example, the first redistribution structure 100 may be formed between the plurality of conductive posts 210 and the external connection terminals 170. When the first redistribution structure 100 is formed between the plurality of conductive posts 210 and the external connection terminals 170, the scale of a line width of the conductive layer 160 is less than the scale of the external connection terminal 170, resulting in a finer manufacturing process. In some cases, when the first redistribution structure 100 is formed between the plurality of conductive posts 210 and the external connection terminals 170, more external connection terminals 170 may be disposed than when the external connection terminals 170 are directly contacting and connected to the plurality of conductive posts 210. For example, the number of the conductive posts 210 may be less than the number of the conductive layers 160 of the first redistribution structure 100. In some cases, the number of the conductive layers 160 is equal to the number of the external connection terminals 170. When the semiconductor package 1 includes more external connection terminals 170, the semiconductor package 1 may receive more stable power supply compared to a semiconductor package that includes fewer external connection terminals 170.

A molding layer 200 and a plurality of conductive posts 210 may be disposed on the first redistribution structure 100. The molding layer 200 may cover the first device 30, the bridge chip 40, and the plurality of conductive posts 210 on the first redistribution structure 100. In some cases, the molding layer 200 may surround side surfaces of the conductive posts 210, side surfaces and a lower surface of the first device 30, and side surfaces and a lower surface of the bridge chip 40. In some cases, the molding layer 200 may cover an upper surface of the first redistribution structure 100. For example, the molding layer 200 may cover an upper surface of the passivation layer 110 and an upper surface of the conductive layers 160. The molding layer 200 may completely seal the first device 30 and the bridge chip 40 between the first redistribution structure 100 and the second redistribution structure 300. The molding layer 200 may cover the side surfaces of the plurality of conductive posts 210 between the first redistribution structure 100 and the second redistribution structure 300. In some cases, an upper layer of the molding layer 200 may be substantially coplanar with an upper surface of the conductive posts 210.

In some cases, for example, the molding layer 200 may include a thermosetting resin, a thermoplastic resin, a UV-curable resin, or a combination thereof. In some cases, for example, the molding layer 200 may include epoxy resin, silicone resin, or a combination thereof. For example, the molding layer 200 may include an EMC.

The plurality of conductive posts 210 may be disposed between the first redistribution structure 100 and the second redistribution structure 300 inside the molding layer 200. The plurality of conductive posts 210 may each provide an electrical connection path between the first redistribution structure 100 and the second redistribution structure 300. In some cases, for example, the plurality of conductive posts 210 may include copper (Cu), aluminum (Al), silver (Ag), gold (Au), tungsten (W), titanium (Ti), or a conductive material including a combination thereof.

The plurality of conductive posts 210 may have an upper surface and a lower surface spaced apart from each other in the vertical direction (e.g., Z direction). The upper surfaces of the plurality of conductive posts 210 may be coplanar with an upper surface of the molding layer 200, and the lower surfaces of the plurality of conductive posts 210 may be coplanar with a lower surface of the molding layer 200. The plurality of conductive posts 210 may directly contact the conductive layer 160 exposed on the upper surface of the passivation layer 110. For example, the lower surfaces of the plurality of conductive posts 210 may be connected to the upper surfaces of the conductive layers 160.

The plurality of conductive posts 210 may each have a cylindrical shape. For example, a diameter of each of the plurality of conductive posts 210 may be constant along the vertical direction (e.g., Z direction). In an embodiment, the plurality of conductive posts 210 may each have a tapered shape with a diameter varying along the vertical direction (e.g., Z direction). For example, a diameter of an upper surface of the conductive post 210 may be less than a diameter of a lower surface of the conductive post 210, or vice versa.

In some embodiments, the second redistribution structure 300 may be disposed on the molding layer 200. For example, the second redistribution structure 300 may cover an upper surface of the molding layer 200, an upper surface of the conductive posts 210, the first device 30, and the bridge chip 40. The second redistribution structure 300 may include one or more redistribution insulating layers 310, a plurality of conductive line patterns 320, and a plurality of conductive vias 330.

The one or more redistribution insulating layers 310 may be stacked in the vertical direction (e.g., Z direction). In some cases, for example, the redistribution insulating layer 310 may include an insulating material such as a photo-imageable dielectric (PID) resin. In some cases, the redistribution insulating layer 310 may include photosensitive polyimide and/or an inorganic filler.

A conductive pattern including the plurality of conductive line patterns 320 and the plurality of conductive vias 330 may be disposed on at least one of upper and lower surfaces of the redistribution insulating layer 310. In some cases, an upper surface of the conductive line patterns 320 may be coplanar with an upper surface of the redistribution insulating layer 310. In some cases, a lower surface of the conductive vias 330 may be coplanar with a lower surface of the redistribution insulating layer 310. The plurality of conductive line patterns 320 may be disposed to extend in the horizontal direction (e.g., X direction and/or Y direction) inside the redistribution insulating layer 310. The plurality of conductive vias 330 may penetrate at least one redistribution insulating layer 310 in the vertical direction (e.g., Z direction). The plurality of conductive vias 330 may be respectively in contact with and electrically connected to some of the plurality of conductive line patterns 320 at a different redistribution insulating layer 310.

In some embodiments, at least some of the plurality of conductive line patterns 320 may be integrally formed with some of the plurality of conductive vias 330. For example, the plurality of conductive line patterns 320 may be integrally formed with the plurality of conductive vias 330 in contact with the upper surfaces of the plurality of conductive line patterns 320 in a lower insulating layer from the one or more redistribution insulating layers 310. In some cases, one or more conductive vias 330 may be in contact with and electrically connected to a conductive line pattern 320.

In some embodiments, the plurality of conductive vias 330 may each have a tapered shape extending from the top to the bottom with a reducing width measured in the horizontal direction (e.g. the X direction). For example, the plurality of conductive vias 330 may each have a narrower width further away from the first semiconductor chip 10. For example, a width of an upper surface of each of the plurality of conductive vias 330 may be greater than a width of a lower surface of each of the plurality of conductive vias 330.

In some cases, for example, a plurality of redistribution patterns including the plurality of conductive line patterns 320 and the plurality of conductive vias 330 may each include a metal such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Be), gallium Ga), ruthenium (Ru), or an alloy thereof, but is not necessarily limited thereto.

The first semiconductor chip 10, the second semiconductor chip 20, and the stiffener 70 may be disposed on an upper surface of the second redistribution structure 300. In some cases, the first device 30, the bridge chip 40, the molding layer 200, and the conductive post 210 may be disposed on a lower surface of the second redistribution structure 300. The first semiconductor chip 10 and the second semiconductor chip 20 may be spaced apart in the horizontal direction (e.g., X direction) on the second redistribution structure 300. In some cases, the first device 30 and the bridge chip 40 may be spaced apart in the horizontal direction (X direction) below the second redistribution structure 300.

The first semiconductor chip 10 may include a first substrate 12 and a first chip pad 14. The second semiconductor chip 20 may include a second substrate 22 and a second chip pad 24. Each of the first substrate 12 and second substrate 22 may include an active surface and an inactive surface that is opposite from the active surface. The active surface may be disposed adjacent to a lower surface of each of the first substrate 12 and second substrate 22.

In some embodiments, one or more of the first semiconductor chip 10 and the second semiconductor chip 20 may be a memory chip or a logic chip. For example, the memory chip may be a volatile memory chip such as dynamic random access memory (DRAM) or static random access memory (SRAM). In some cases, for example, the memory chip may be a non-volatile memory chip such as phase-change random access memory (PRAM), magnetoresistive random access memory (MRAM), ferroelectric random access memory (FeRAM), or resistive random access memory (RRAM). In some cases, for example, the logic chip may be a microprocessor, an analog element, or a digital signal processor.

The first substrate 12 and second substrate 22 may each include an integrated circuit. The integrated circuit may be a memory circuit, a logic circuit, or any type of integrated circuit including a combination thereof. For example, the memory circuit may include a dynamic random access memory (DRAM) circuit, a static random access memory (SRAM) circuit, a flash memory circuit, an electrically erasable and programmable read-only memory (EEPROM) circuit, a phase-change random access memory (PRAM) circuit, a magnetic random access memory (MRAM) circuit, a resistive random access memory (RRAM) circuit, or a combination thereof. In some cases, for example, the logic circuit may include a central processing unit (CPU) circuit, a graphics processing unit (GPU) circuit, a controller circuit, an application specific integrated circuit (ASIC) circuit, an application processor (AP) circuit, or a combination thereof.

In some cases, the first substrate 12 and second substrate 22 may each include a semiconductor material, such as a Group IV semiconductor material, a Group III-V semiconductor material, a Group II-VI semiconductor material, or a combination thereof. For example, the Group IV semiconductor material may include silicon (Si), germanium (Ge), or a combination thereof. For example, the III-V semiconductor material may include gallium arsenide (GaAs), indium phosphorus (InP), gallium phosphorus (GaP), indium arsenide (InAs), indium antimony (InSb), indium gallium arsenide (InGaAs), or a combination thereof. For example, the group II-VI semiconductor material may include zinc telluride (ZnTe), cadmium sulfide (CdS), or a combination thereof.

The first chip pad 14 and second chip pad 24 may be respectively disposed on the lower surface of the first substrate 12 and second substrate 22, and may respectively extend along the lower surfaces of each of the first substrate 12 and second substrate 22 which are the active surfaces. In some cases, a first connection member 16 may be disposed between the first semiconductor chip 10 and the second redistribution structure 300. For example, the first connection member 16 may be disposed between a lower surface of the first chip pad 14 and an upper surface of the second redistribution structure 300. In some cases, a second connection member 26 may be disposed between the second semiconductor chip 20 and the second redistribution structure 300. For example, the second connection member 26 may be disposed between a lower surface of the first chip pad 14 and an upper surface of the second redistribution structure 300.

The first chip pad 14 may be in contact with the first connection member 16, and the second chip pad 24 may be in contact with the second connection member 26. Each of the first connection member 16 and second connection member 26 may contact the conductive line pattern 320 and/or the conductive via 330 of the second redistribution structure 300. Accordingly, the first connection member 16 may provide an electrical connection path between the first semiconductor chip 10 and the second redistribution structure 300, and the second connection member 26 may provide an electrical connection path between the second semiconductor chip 20 and the second redistribution structure 300.

In some cases, for example, the first chip pad 14 and second chip pad 24 may include copper (Cu), aluminum (Al), silver (Ag), gold (Au), tungsten (W), titanium (Ti), or a conductive material including a combination thereof. In some cases, for example, the first connection member 16 and second connection member 26 may each include a solder ball or a solder bump.

The stiffener 70 may have a quadrangular ring shape surrounding the first semiconductor chip 10 and the second semiconductor chip 20 when viewed from the upper surface of the semiconductor package 1. For example, the first semiconductor chip 10 and the second semiconductor chip 20 may be disposed in the opening (e.g., described with reference to FIG. 1A) of the stiffener 70. In some cases, the first semiconductor chip 10 and the second semiconductor chip 20 may be spaced apart from a side surface (or side wall) of the opening of stiffener 70 by a constant interval, where the constant interval may range from about 2 mm to about 3 mm. An upper surface of the stiffener 70 may be disposed at a lower vertical level than the upper surfaces of the first semiconductor chip 10 and second semiconductor chip 20. For example, with respect to the upper surface of the second redistribution structure 300, a height H1, measured in the vertical direction, of the stiffener 70 may be less than a height H2, measured in the vertical direction, of each of the first semiconductor chip 10 and the second semiconductor chip 20. As a result, heat may be effectively dissipated from the first semiconductor chip 10 and the second semiconductor chip 20.

The first device 30 may be disposed on the lower surface of the second redistribution structure 300. The first device 30 may include various types of passive components or various forms of surface mountable components. For example, the first device 30 may be referred to as a passive device. For example, a passive component may include one or more of a resistor, a capacitor, an inductor, a thermistor, an oscillator, a ferrite bead, an antenna, a varistor, and/or a crystal. For example, the passive component may include a Multi Layer Ceramic Capacitor (MLCC), Low Inductance Chip Capacitor (LICC), Land Side Capacitor (LSC), Integrated Passive Device (IPD), etc.

A third connection member 32 may be disposed between the first device 30 and the second redistribution structure 300. The first device 30 may be electrically connected to the second redistribution structure 300 through the third connection member 32. For example, the third connection member 32 may be a solder ball or solder bump.

The bridge chip 40 may be disposed on the lower surface of the second redistribution structure 300. In some cases, the bridge chip 40 may be spaced apart from the first device 30 in the horizontal direction (e.g., the X direction). The bridge chip 40 may provide an electrical connection path between the first semiconductor chip 10 and the second semiconductor chip 20 disposed on the second redistribution structure 300. For example, the first semiconductor chip 10 and the second semiconductor chip 20 may be electrically connected to each other through a bridge circuit within the bridge chip 40. As shown in FIG. 3A, each of the first semiconductor chip 10 and second semiconductor chip 20 may overlap at least a portion of the bridge chip 40 in the vertical direction (e.g., Z direction).

The bridge chip 40 may include a bridge substrate 42 and a bridge circuit. The bridge chip 40 might not be directly electrically connected to the first redistribution structure 100, but may be electrically connected to the first redistribution structure 100 through the conductive post 210 and the second redistribution structure 300.

An active surface of the bridge substrate 42 may be disposed adjacent to an upper surface of the bridge substrate 42, and an inactive surface of the bridge substrate 42 may be disposed adjacent to a lower surface of the bridge substrate 42. The bridge substrate 42 may include a semiconductor material such as a Group IV semiconductor material, a Group III-V semiconductor material, a Group II-VI semiconductor material, or a combination thereof. For example, the Group IV semiconductor material may include silicon (Si), germanium (Ge), or a combination thereof. For example, the III-V semiconductor material may include gallium arsenide (GaAs), indium phosphorus (InP), gallium phosphorus (GaP), indium arsenide (InAs), indium antimony (InSb), indium gallium arsenide (InGaAs), or a combination thereof. For example, the group II-VI semiconductor material may include zinc telluride (ZnTe), cadmium sulfide (CdS), or a combination thereof. In some cases, the bridge substrate 42 may include glass or ceramic.

The bridge circuit may be formed within the bridge substrate 42. The bridge circuit may have a pitch corresponding to a fine pitch of a chip pad of each of the first semiconductor chip 10 and second semiconductor chip 20. The bridge circuit may have a finer pitch than the conductive layer 160. For example, a line width of the bridge circuit may be less than a line width of the conductive layer 160.

A fourth connection member 44 may be disposed between the bridge chip 40 and the second redistribution structure 300. The fourth connection member 44 may electrically connect the second redistribution structure 300 to the bridge chip 40. The fourth connection member 44 may contact the conductive line pattern 320 and/or the conductive via 330 of the second redistribution structure 300. For example, the fourth connection member 44 may include a conductive pillar. For example, the fourth connection member 44 may have a single cylindrical shape. For example, a diameter of the fourth connection member 44 may be constant along the vertical direction (e.g., Z direction). In an embodiment, the fourth connection member 44 may have a tapered shape with a diameter varying along the vertical direction (e.g., Z direction). For example, the fourth connection member 44 may include copper (Cu), aluminum (Al), silver (Ag), gold (Au), tungsten (W), titanium (Ti), or a conductive material including a combination thereof.

In an embodiment, each of the first device 30 and the bridge chip 40 may include a chip pad. When the first device 30 includes a chip pad, a first device chip pad may contact the third connection member 32. In some cases, the first device chip pad may be disposed between the first device 30 and the third connection member 32. In some cases, when the bridge chip 40 includes a chip pad, a bridge chip pad may contact the fourth connection member 44. In some cases, the bridge chip pad may be disposed between the bridge chip 40 and the fourth connection member 44.

In some embodiments the semiconductor package 1 may include an underfill layer 50 surrounding the third connection member 32 and the fourth connection member 44. For example, the underfill layer 50 may be disposed between the first device 30 and the second redistribution structure 300. For example, the underfill layer 50 may be disposed between the bridge chip 40 and the second redistribution structure 300. The underfill layer 50 may fill a space between the first device 30 and the second redistribution structure 300 and a space between the bridge chip 40 and the second redistribution structure 300. The underfill layer 50 may include an outer surface having an inclination. The underfill layer 50 may include epoxy resin or two or more types of silicone hybrid materials. Accordingly, the third connection member 32 and the fourth connection member 44 may contact the underfill layer 50. However, the inventive concept is not necessarily limited thereto, and the underfill layer 50 may be omitted.

The first device 30 and the bridge chip 40 may be disposed at a vertical level higher than the upper surface of the first redistribution structure 100. In some cases, the first device 30 and the bridge chip 40 may be arranged to be spaced apart from the upper surface of the first redistribution structure 100 in the vertical direction (Z direction). For example, the first device 30 and the bridge chip 40 may be spaced apart from the first redistribution structure 100. For example, the molding layer 200 may be disposed between the first device 30 and the first redistribution structure 100 and between the bridge chip 40 and the first redistribution structure 100.

In some cases, inside the molding layer 200, the first device 30 may have a third height H3, measured in the vertical direction (e.g., the Z direction) and the bridge chip 40 may have a fourth height H4, measured in the vertical direction (e.g., the Z direction). The third height H3 and the fourth height H4 may be different from each other. In an embodiment, the third height H3 may be greater than the fourth height H4, or vice versa. In an embodiment, the third height H3 and the fourth height H4 may be equal to each other.

The semiconductor package 1 according to the present inventive concept may first form the stiffener 70 including a plurality of openings each having a quadrangular cross-section, thereby securing mechanical stability without a wafer supporting system (WSS) process.

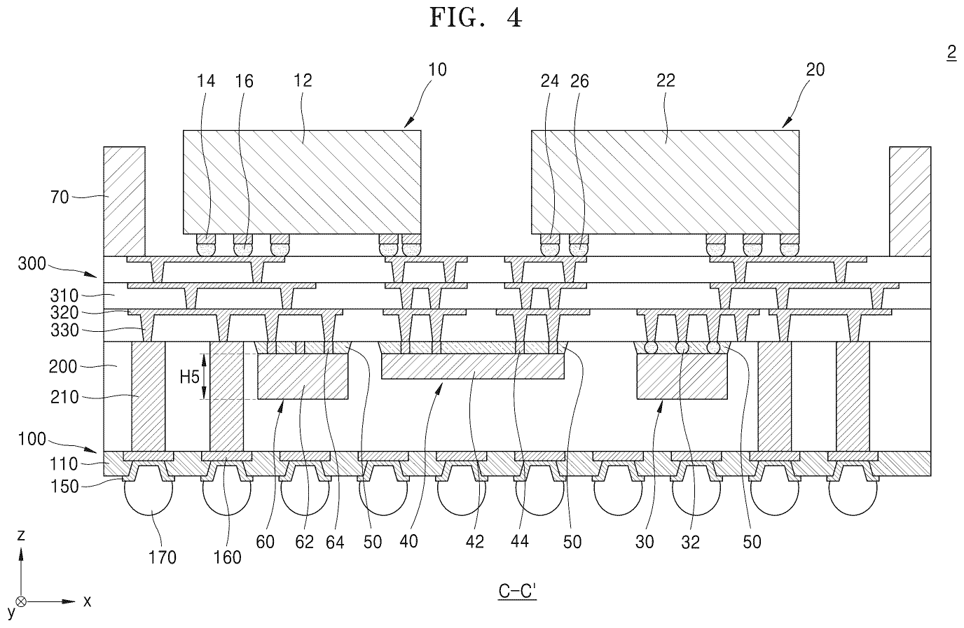

FIG. 4 is an example of a cross-sectional of a semiconductor package 2 according to according to an embodiment of the present inventive concept. The semiconductor package 2 of FIG. 4 is described with reference to FIGS. 3A and 3B. In some cases, the differences between the semiconductor package 1 in FIG. 3B and the semiconductor package 2 in FIG. 4 are described.

Referring to FIG. 4, the semiconductor package 2 may include the first semiconductor chip 10, the second semiconductor chip 20, the first device 30, the bridge chip 40, a second device 60, the first redistribution structure 100, the molding layer 200, the second redistribution structure 300, and the stiffener 70. The first semiconductor chip 10, the second semiconductor chip 20, the first device 30, the bridge chip 40, the first redistribution structure 100, the molding layer 200, the second redistribution structure 300, and the stiffener 70 of the semiconductor package 2 of FIG. 4 are substantially the same as first semiconductor chip 10, the second semiconductor chip 20, the first device 30, the bridge chip 40, the first redistribution structure 100, the molding layer 200, the second redistribution structure 300, and the stiffener 70 of the semiconductor package 1 of FIG. 3B, respectively. Accordingly, the second device 60 is described below.

The second device 60 may be disposed on a lower surface of the second redistribution structure 300. For example, the second device 60 may be spaced apart from the first redistribution structure 100 in the vertical direction (e.g., the Z direction). The second device 60 may be spaced apart from each of the first device 30 and the bridge chip 40 in the horizontal direction (e.g., X direction and/or Y direction). Each of the first device 30, bridge chip 40, and second device 60 may be surrounded by the molding layer 200.

For example, the second device 60 may include a chiplet. The chiplet may include a plurality of IP blocks, and the plurality of IP blocks may perform different functions. Each of the plurality of IP blocks may include a plurality of integrated circuits. In an embodiment, the second device 60 may be an active device. In an embodiment, the second device 60 may be a semiconductor chip. For example, the second device 60 may be an input/output chip (I/O chip) or a power management chip. The power management chip may include a power management integrated circuit (PMIC). In some cases, the second device 60 may include a second device substrate 62, where the second device substrate 62 includes the plurality of IP blocks.

The second device 60 may be spaced apart from the first redistribution structure 100 in the vertical direction (Z direction). For example, the molding layer 200 may be disposed between the second device 60 and the first redistribution structure 100. For example, the molding layer 200 may cover a lower surface and side surfaces of the second device 60.

In some cases, the second device 60 may have a fifth height H5 measured from an upper surface to a lower surface of the second device 60. The third, fourth, and fifth heights H3, H4, and H5 may be different from each other. In an embodiment, at least two of the third, fourth, and fifth heights H3, H4, and H5 may be the same. For example, the third height H3 and the fifth height H5 may be the same.

A fifth connection member 64 may be disposed between the second device 60 and the second redistribution structure 300. The second device 60 may be electrically connected to the second redistribution structure 300 through the fifth connection member 64. The fifth connection member 64 may contact the conductive line pattern 320 and/or the conductive via 330 of the second redistribution structure 300. The plurality of fifth connection members 64 may also be surrounded by the underfill layer 50.

In an embodiment, the second device 60 may include a chip pad. When the second device 60 includes a second device chip pad, the second device chip pad may contact the fifth connection member 64. For example, the second device chip pad may be disposed between and in contact with an upper surface of the second device and a lower surface of the fifth connection member 64. In some cases, fifth connection member 64 may be an example of, or includes aspects of, the fourth connection member 44 described with reference to FIG. 3B.

In some cases, in each of the semiconductor package 1 and the semiconductor package 2, the fourth connection member 44 may include a solder ball, and the third connection member 32 may include a conductive pillar. The conductive pillar may have a single cylindrical shape. For example, a diameter of the conductive pillar may be constant along the vertical direction (e.g., Z direction). In an embodiment, the conductive pillar may have a tapered shape with a diameter varying along the vertical direction (e.g., Z direction). For example, the third connection member 32 and fourth connection member 44 may each include copper (Cu), aluminum (Al), silver (Ag), gold (Au), tungsten (W), titanium (Ti), or a conductive material including a combination thereof. In some cases, the third connection member 32 and fourth connection member 44 may be modified in various ways.

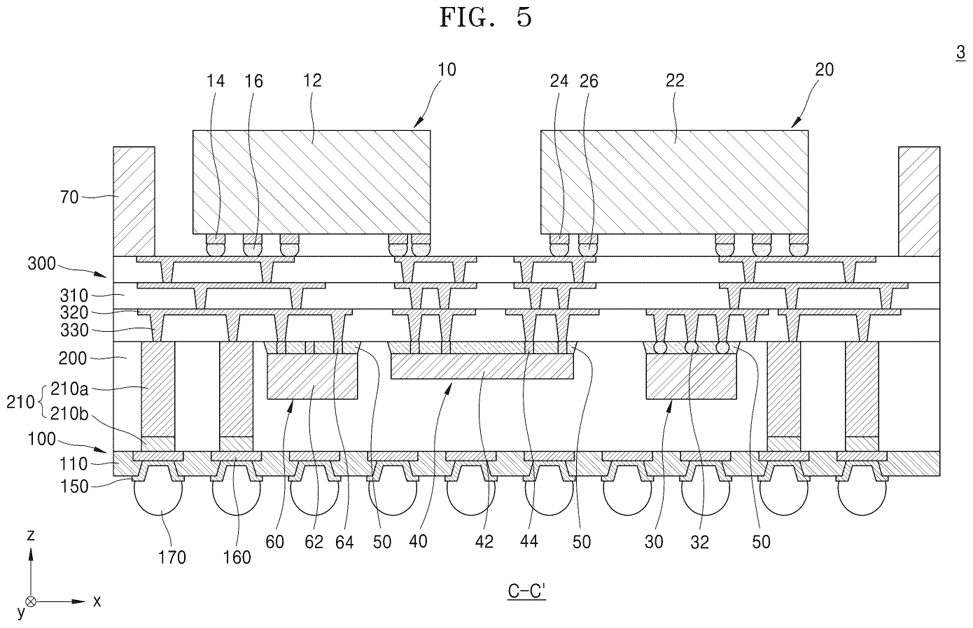

FIG. 5 is an example of a cross-sectional view of a semiconductor package 3 according to according to an embodiment of the present inventive concept. The semiconductor package 3 of FIG. 5 is described with reference to FIG. 4. In some cases, differences between the semiconductor package 2 in FIG. 4 and the semiconductor package 3 in FIG. 5 are described.

Referring to FIG. 5, the semiconductor package 3 may include the first semiconductor chip 10, the second semiconductor chip 20, the first device 30, the bridge chip 40, the second device 60, the first redistribution structure 100, the molding layer 200, the second redistribution structure 300, and the stiffener 70. The first semiconductor chip 10, the second semiconductor chip 20, the first device 30, the bridge chip 40, the second device 60, the first redistribution structure 100, the molding layer 200, the second redistribution structure 300, and the stiffener 70 of the semiconductor package 3 of FIG. 5 are substantially the same as the first semiconductor chip 10, the second semiconductor chip 20, the first device 30, the bridge chip 40, the second device 60, the first redistribution structure 100, the molding layer 200, the second redistribution structure 300, and the stiffener 70 of FIG. 4, respectively. Accordingly, the differences in the conductive post 210 are described below.

In some embodiments, the conductive post 210 may include a pillar portion 210a including copper (Cu) and a connection layer 210b that allows the pillar portion 210a to connect to the first redistribution structure 100. In some cases, the pillar portion 210a of the conductive post 210 is disposed on the connection layer 210b of the conductive post 210. In some cases, for example, an upper surface of the pillar portion 210a of the conductive post 210 may be disposed on and in contact with lower surfaces of the conductive vias 330 and/or the conducive line patterns 320 of the second redistribution structure 300. In some cases, a lower surface of the connection layer 210b of the conductive post 210 may be disposed on and in contact with an upper surface of the conductive layer 160 of the first redistribution structure 100. The connection layer 210b may include lead (Pb), but a material of the connection layer 210b is not necessarily limited thereto.

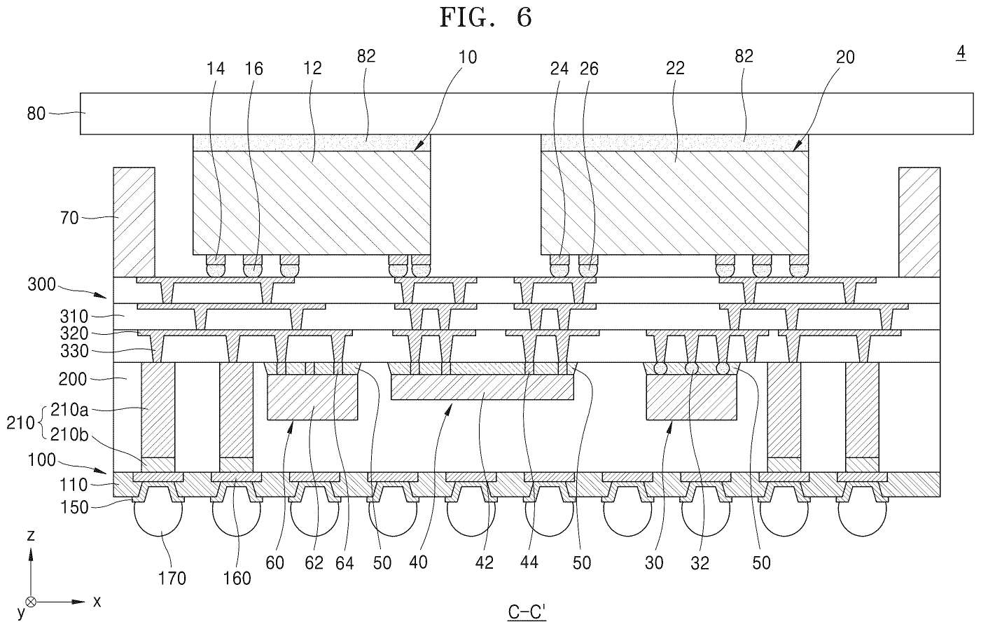

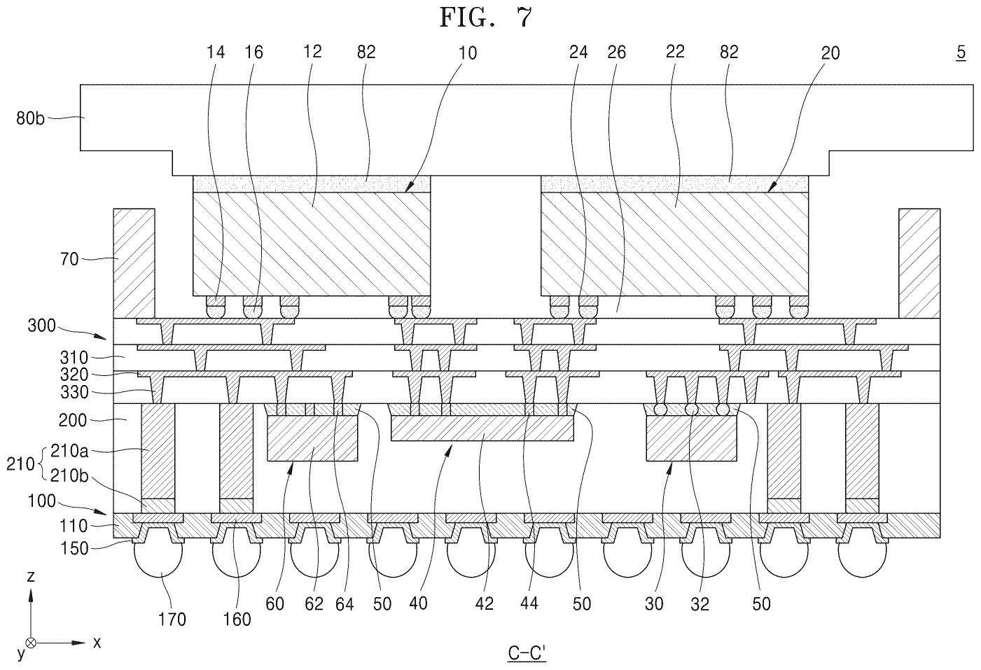

FIG. 6 is an example of a cross-sectional view of a semiconductor package 4 according to according to an embodiment of the present inventive concept. FIG. 7 is an example of a cross-sectional view of a semiconductor package 5 according to according to an embodiment of the present inventive concept. Referring to FIGS. 6 and 7, semiconductor packages 4 in FIGS. 6 and 5 in FIG. 7 may respectively include heat sinks 80 in FIG. 6 and heat sink 80b in FIG. 7.

Referring to FIG. 6, the first semiconductor chip 10 and second semiconductor chip 20 may be connected to the heat sink 80 through an interface material layer 82. For example, the interface material layer 82 is disposed between the heat sink 80 and upper surfaces of each of the first semiconductor chip 10 and second semiconductor chip 20. In an embodiment, the heat sink 80 may include a first heat sink and a second heat sink, where the first heat sink and the second heat sink are connected to the first semiconductor chip 10 and second semiconductor chip 20, respectively. The interface material layer 82 may include a thermally conductive and electrically insulating material. For example, the interface material layer 82 may include a polymer including metal powder such as silver or copper, thermal grease, white grease, or a combination thereof. The heat sink 80 may directly contact the first semiconductor chip 10 and second semiconductor chip 20 through the interface material layer 82, thereby improving heat dissipation characteristics. As shown in FIG. 6, an upper surface of the stiffener 70 is spaced apart from a bottom surface of the heat sink 80, but the arrangement of the stiffener 70 is not necessarily limited thereto. For example, the upper surface of the stiffener 70 may be formed to be in direct contact with the bottom surface of the heat sink 80. In some cases, an interface material layer may be disposed on the upper surface of the stiffener 70, and the stiffener 70 may contact the heat sink 80 through the interface material layer. In a plan view, the heat sink 80 may have a shape protruding into openings of the stiffener 70.

Referring to FIG. 7, the interface material layer 82 in FIG. 7 is the same as the interface material layer 82 in FIG. 6, and thus, a description thereof is omitted. Accordingly, differences between the heat sink 80b in FIG. 7 and the heat sink 80 in FIG. 6 are described.

The heat sink 80b may include a protrusion portion protruding downward from a portion in contact with the first semiconductor chip 10 and second semiconductor chip 20 through the interface material layer 82. As shown in FIG. 7, the upper surface of the stiffener 70 is spaced apart from a bottom surface of the heat sink 80b, but the arrangement of the stiffener 70 is not necessarily limited thereto. For example, the upper surface of the stiffener 70 may be formed to be in direct contact with the bottom surface of the heat sink 80b. In some cases, an interface material layer may be disposed on the upper surface of the stiffener 70, and the stiffener 70 may contact the heat sink 80b through the interface material layer. In a plan view, the heat sink 80b may have a shape protruding into openings of the stiffener 70.

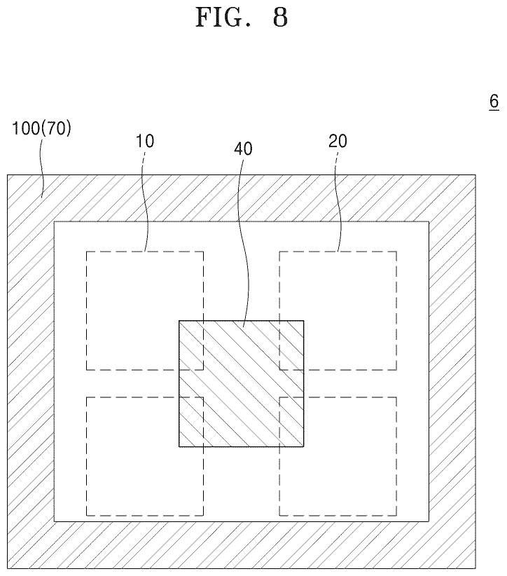

FIG. 8 is an example of a plan view of a semiconductor package 6 according to according to an embodiment of the present inventive concept. For the convenience of describing the embodiment, the first semiconductor chip 10, the second semiconductor chip 20, the bridge chip 40, the first redistribution structure 100, and the stiffener 70 are shown in FIG. 8. The semiconductor package 6 in FIG. 8 is described with reference to FIGS. 3A and 3B. For example, the differences between the semiconductor package 1 in FIGS. 3A and 3B and the semiconductor package 6 in FIG. 8 are described.

Referring to FIG. 8, the bridge chip 40 may be disposed on a lower surface of the second redistribution structure 300. The bridge chip 40 may provide an electrical connection path between the first semiconductor chip 10 and the second semiconductor chip 20 disposed on the second redistribution structure 300. For example, the first semiconductor chip 10 and the second semiconductor chip 20 may be electrically connected to each other through a bridge circuit inside the bridge chip 40. As shown in FIG. 8, two first semiconductor chips 10 spaced apart in the horizontal direction (e.g., the Y direction) and two second semiconductor chips 20 spaced apart in the horizontal direction (e.g., the Y direction) may each overlap at least a portion of the bridge chip 40 in the vertical direction (e.g., Z direction). For example, the bridge chip 40 is disposed about a center region of the opening in the stiffener 70. In the plan view, each of the four corners of the bridge chip 40 may overlap a corner region of each of the two first semiconductor chips 10 and each of the two second semiconductor chips 20.

However, the inventive concept is not necessarily limited thereto, and the first semiconductor chip 10, the second semiconductor chip 20, and the bridge chip 40 may be disposed in various ways. The bridge chip 40 may electrically connect a plurality of semiconductor chips to each other. In contrast to the embodiment shown in FIG. 3A, a bridge chip 40 may be disposed on a lower surface of the second redistribution structure to electrically connect a plurality of semiconductor chips to each other.

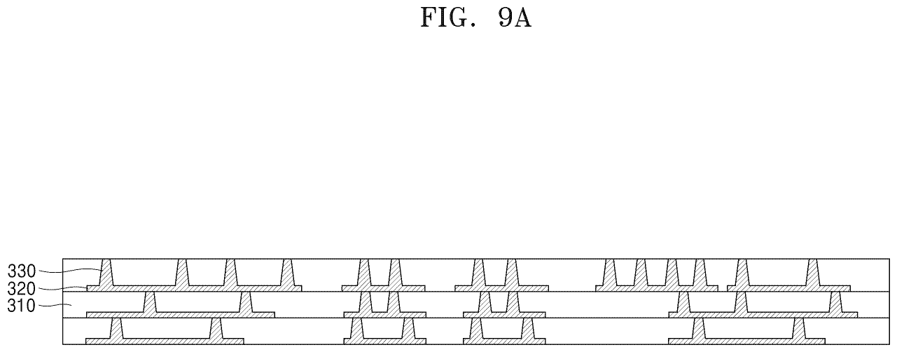

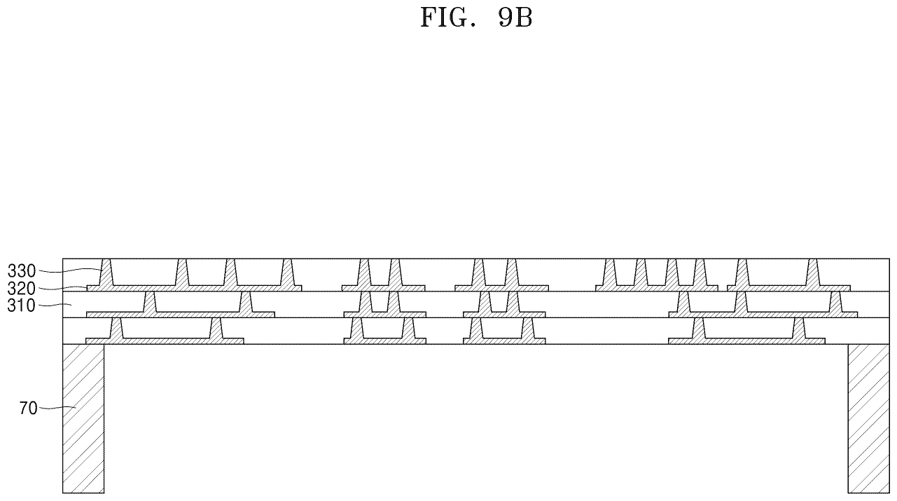

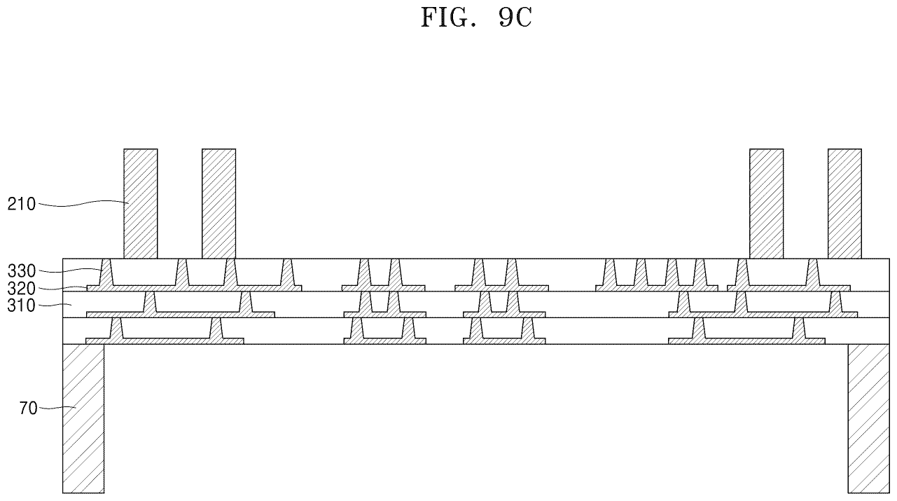

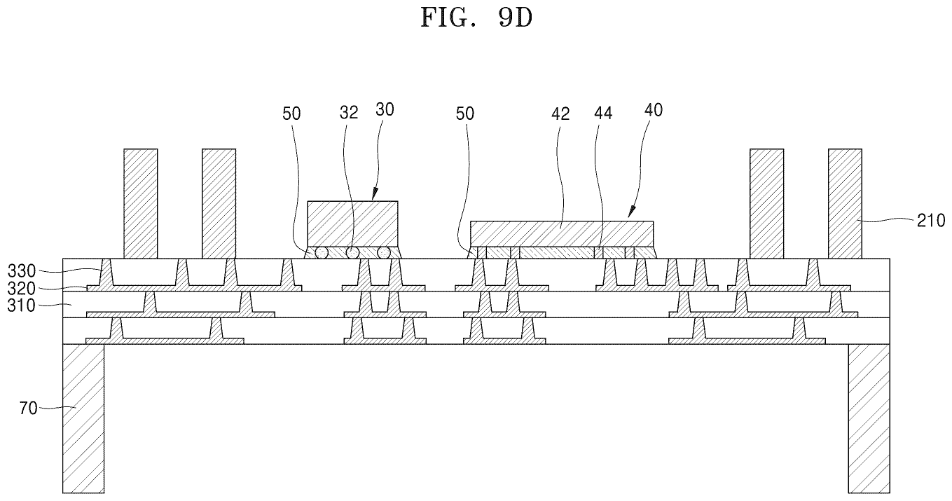

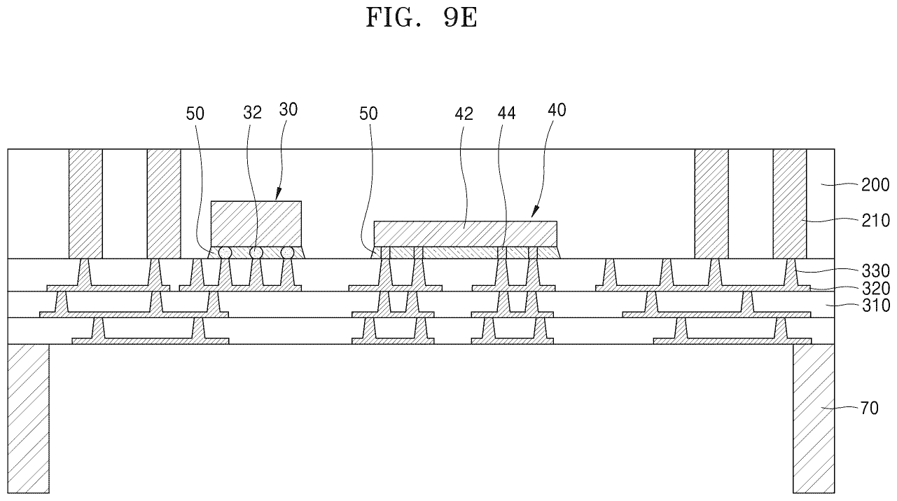

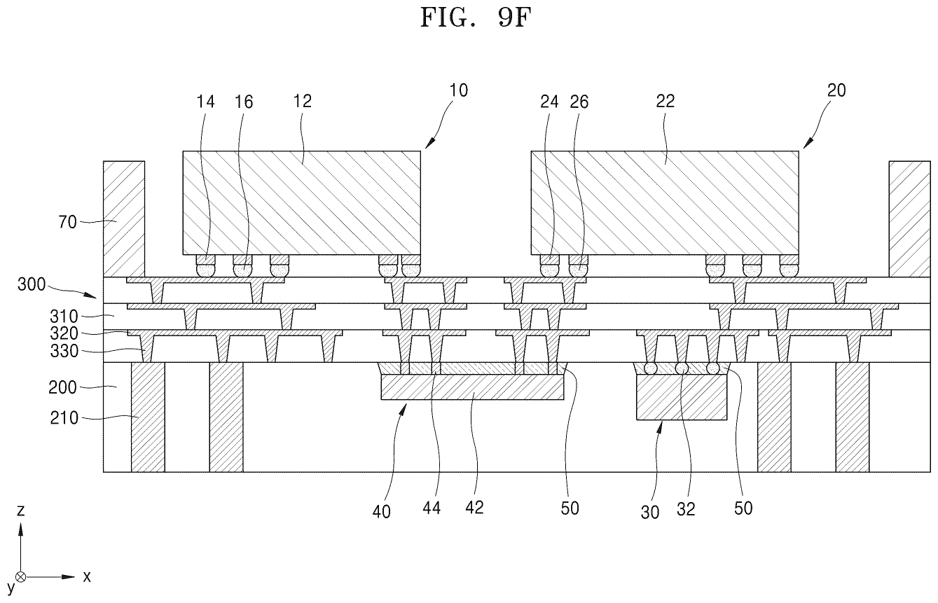

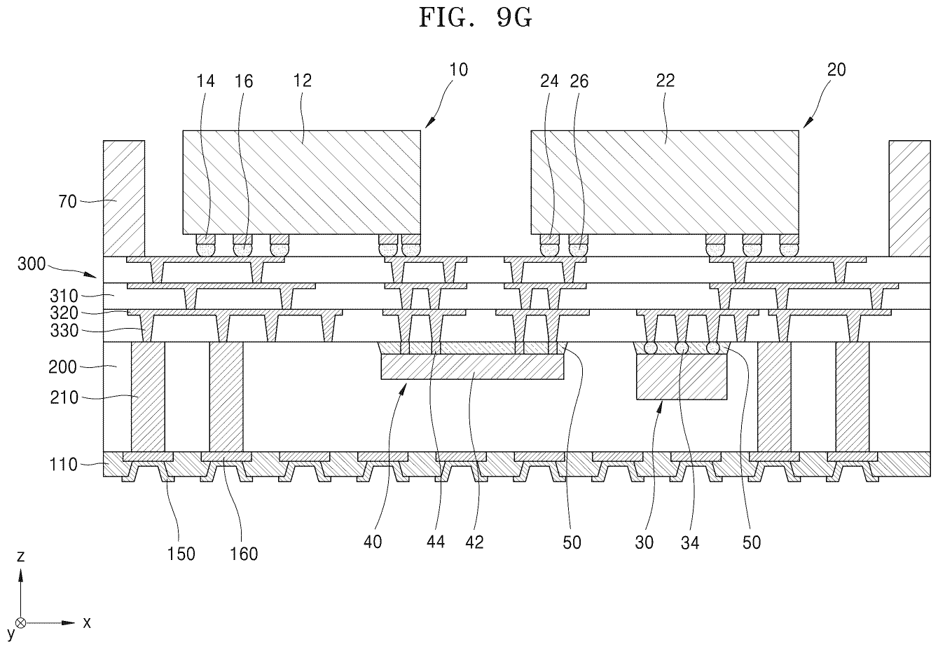

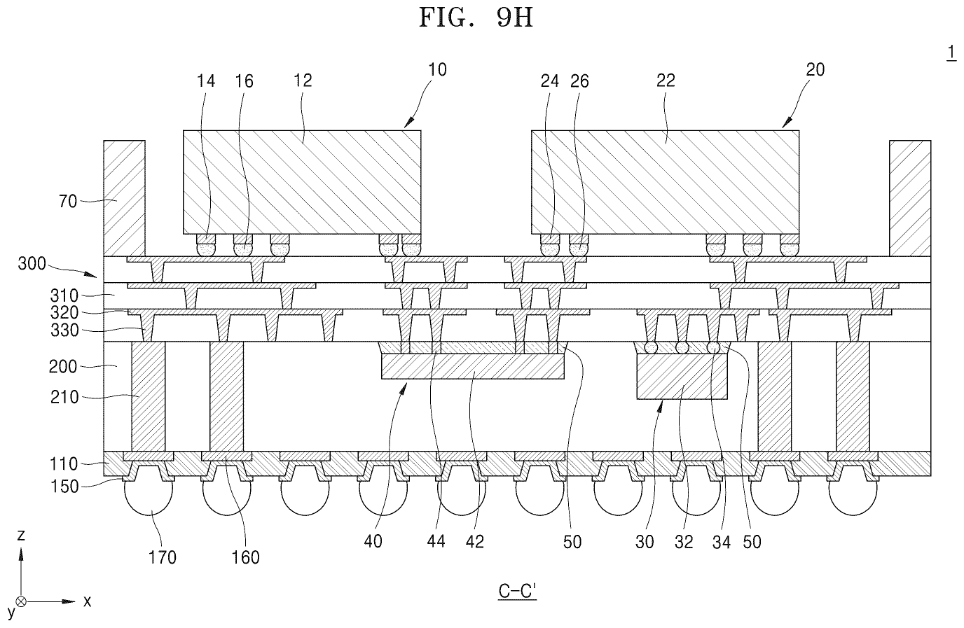

FIGS. 9A to 9H are examples of cross-sectional views of a method for manufacturing a semiconductor package according to an embodiment of the present inventive concept. The method of FIGS. 9A to 9H is described with reference to FIGS. 1A to 8.

Referring to FIG. 9A, the second redistribution structure 300 may be formed. The second redistribution structure 300 may include the one or more redistribution insulating layers 310, the conductive line pattern 320, and the conductive via 330. For example, each of the one or more redistribution insulating layers 310 may include a plurality of conductive line patterns 320 and a plurality of conductive vias 330 disposed on the conductive line patterns 320.

The one or more redistribution insulating layers 310 may be stacked in the vertical direction (e.g., Z direction). The conductive line pattern 320 may extend in the horizontal direction (e.g., X direction and/or Y direction) inside the redistribution insulating layer 310. The conductive via 330 may extend in the vertical direction (e.g., Z direction) inside the redistribution insulating layer 310 and may be electrically connected to at least one conductive line pattern 320.

First, the lowermost bottom conductive line pattern 320 is formed and a preliminary lowermost redistribution insulating layer is formed to cover the lowermost bottom conductive line pattern 320. Then, at least a portion of the preliminary lowermost redistribution insulating layer may be removed by performing an exposure process, and the lowermost redistribution insulating layer 310 including a via hole may be formed. The via hole may be formed to have a narrow horizontal width from an upper surface of the lowermost redistribution insulating layer 310 to a lower surface thereof. A base redistribution conductive layer may be formed and patterned on the lowermost redistribution insulating layer 310, and a base conductive pattern including the conductive line pattern 320 and the conductive via 330 may be formed. Then, the second redistribution structure 300 may be formed by repeatedly forming the redistribution insulating layer 310 and conductive patterns.

Referring to FIG. 9B, the stiffener 70 may be formed. The stiffener 70 may include openings extending from an upper surface to a lower surface. As described below, a semiconductor chip may be disposed in the opening of the stiffener 70. Referring to FIGS. 1A-1C, 2A, and 2B, in some embodiments, the stiffener 70 may be disposed on the second redistribution structure 300 through an adhesive layer. In some cases, the stiffener 70 is disposed on a bottom surface of the lowermost redistribution insulating layer 310. For example the adhesive layer may be disposed between the stiffener 70 and the second redistribution structure 300.

Referring to FIG. 9C, the conductive post 210 may be formed. For example, the conductive post 210 may be disposed on a topmost redistribution insulating layer 310 of the second redistribution structure 300. For example, the conductive post 210 may include copper (Cu), aluminum (Al), silver (Ag), gold (Au), tungsten (W), titanium (Ti), or a conductive material including a combination thereof. In some embodiments, as described with reference to FIG. 6, the conductive post 210 may include the pillar portion 210a including copper (Cu) and the connection layer 210b that allows the pillar portion 210a to connect to the first redistribution structure 100. For example, the connection layer 210b may include lead (Pb), but a material of the connection layer 210b is not necessarily limited thereto.

Referring to FIG. 9D, the first device 30 and the bridge chip 40 may be attached to the second redistribution structure 300. Each of the first device 30, the bridge chip 40, and the conductive post 210 may be spaced apart from each other in the horizontal direction (e.g., X direction). In some cases, each of the first device 30, the bridge chip 40, and the conductive post 210 may be disposed on the conductive vias 330 of the second redistribution structure 300.

The first device 30 may be disposed on and connected to the third connection member 32, and the bridge chip 40 may be disposed on and connected to the fourth connection member 44. In some cases, an underfill layer 50 is disposed on the second redistribution structure 300. The underfill layer 50 may surround and cover the third connection member 32 and the fourth connection member 44, but the inventive concept is not necessarily limited thereto.

For example, the first device 30 may be connected to the second redistribution structure 300 using a solder bonding method, and the bridge chip 40 may be connected to the second redistribution structure 300 using an oxide bonding method. Accordingly, the third connection member 32 may include a solder ball, and the fourth connection member 44 may include a conductive pillar. However, the bonding method of the first device 30 and/or the bridge chip 40 may be modified in various ways.

Referring to FIG. 9E, the molding layer 200 may be formed on the second redistribution structure 300 by forming a molding material surrounding the first device 30, the bridge chip 40, and the conductive post 210. In some cases, the molding material may cover an upper surface of the conductive post 210. In some cases, a portion of the molding material is removed to form the molding layer 200.

A material of the molding material may be the same as a material of the molding layer 200 described with reference to FIG. 3B. After the molding material is formed, an upper portion of the molding material and an upper portion of the conductive post 210 may be removed by grinding. The molding layer 200 may be formed by grinding the molding material. When the removal process of the molding layer 200 is completed, an upper surface of the molding layer 200 may be coplanar with an upper surface of the conductive post 210. For example, an upper surface of the conductive post 210 is exposed.

Referring to FIG. 9F, the semiconductor package may be rotated or flipped for 180 degrees about its center axis. FIG. 9F may show an inverted form (or upside-down version) of the result of FIG. 9E. Then, the first semiconductor chip 10 and the second semiconductor chip 20 may be disposed on the second redistribution structure 300. The first semiconductor chip 10 and the second semiconductor chip 20 may be disposed in the opening of the stiffener 70. In some cases, the stiffener 70 surrounds the first semiconductor chip 10 and the second semiconductor chip 20. In some cases, the stiffener 70, the first semiconductor chip 10, and the second semiconductor chip 20 may be spaced apart from each other in the horizontal direction (e.g., the X direction). The first semiconductor chip 10 may include the first substrate 12 and the first chip pad 14, and the second semiconductor chip 20 may include the second substrate 22 and the second chip pad 24.

The first connection member 16 may be disposed between the first semiconductor chip 10 and the second redistribution structure 300, and the second connection member 26 may be disposed between the second semiconductor chip 20 and the second redistribution structure 300. For example, the first connection member 16 may be disposed between the first chip pad 14 and the second redistribution structure 300, and second connection member 26 may be disposed between the second chip pad 24 and the second redistribution structure 300. The first connection member 16 and the second connection member 26 may be electrically connected to the conductive line pattern 320 and/or the conductive via 330 of the second redistribution structure 300.

Referring to FIG. 9G, the first redistribution structure 100 may be formed on the molding layer 200. For example, the first redistribution structure 100 may be disposed below the molding layer 200. The first redistribution structure 100 may include the passivation layer 110, the UBM layer 150, and the conductive layer 160. The passivation layer 110 may completely cover lower and side surfaces of the conductive layer 160 and expose an upper surface of the conductive layer 160. In some cases, a part of a lower surface of the passivation layer 110 may be covered by the UBM layer 150.

To form the first redistribution structure 100, the conductive layer 160 may first be formed on the lower surface of the molding layer 200. The conductive layer 160 may be formed through a plating process. Then, a seed layer may be formed on the edge of the conductive layer 160 to prevent a metal material of the conductive layer 160 from diffusing into the passivation layer 110. After the conductive layer 160 is formed, a first operation of forming the passivation layer 110 covering the conductive layer 160 and including a via hole, a second operation of forming a UBM via to fill the via hole, and a third operation of forming a UBM pad integrally formed with the UBM via and covering a part of the lower surface of the passivation layer 110 may be performed. The second and third operations of respectively forming the UBM via and UBM pad may include a plating process. In the first operation, the passivation layer 110 may be formed, for example, by lamination, application, chemical vapor deposition (CVD), physical vapor deposition (PVD), or a combination thereof.

Referring to FIG. 9H, the semiconductor package 1 may be completed by connecting the external connection terminal 170 to the UBM layer 150. For example, the external connection terminal 170 may include a solder ball structure or a conductive bump structure.

Although embodiments of the present disclosure have been described with reference to the accompanying drawings, the present disclosure is not necessarily limited to the above embodiments, but may be implemented in various different forms. A person skilled in the art may appreciate that the present disclosure may be practiced in other concrete forms without changing the technical spirit or essential characteristics of the present disclosure. Therefore, it should be appreciated that the embodiments as described above is not restrictive but illustrative in all respects.

What is claimed is:

1. A semiconductor package comprising:
a first redistribution structure;
a second redistribution structure disposed on the first redistribution structure;
a semiconductor chip disposed on an upper surface of the second redistribution structure;
a bridge chip disposed on a lower surface of the second redistribution structure;
a molding layer disposed between the first redistribution structure and the second redistribution structure, wherein the molding layer surrounds the bridge chip; and
a stiffener disposed on the upper surface of the second redistribution structure, wherein the stiffener comprises an opening,
wherein the semiconductor chip is disposed in the opening of the stiffener.

2. The semiconductor package of claim 1, wherein a horizontal cross-section of the opening of the stiffener is a quadrangular shape.

3. The semiconductor package of claim 1, wherein an upper surface of the stiffener is disposed at a lower vertical level than an upper surface of the semiconductor chip.

4. The semiconductor package of claim 1, further comprising:
an adhesive layer disposed between a lower surface of the stiffener and the upper surface of the second redistribution structure.

5. The semiconductor package of claim 1, wherein the semiconductor chip disposed in the opening of the stiffener is spaced apart from a side wall of the opening of the stiffener by a constant interval.

6. The semiconductor package of claim 5, wherein the constant interval ranges from about 2 mm to about 3 mm.

7. The semiconductor package of claim 1, wherein:
the bridge chip is electrically connected to the first redistribution structure through the second redistribution structure,
wherein the bridge chip overlaps a portion of the semiconductor chip in a vertical direction, and
wherein the vertical direction is perpendicular to the upper surface of the second redistribution structure.

8. The semiconductor package of claim 1, further comprising:
a conductive post disposed inside the molding layer and spaced apart from the bridge chip in a horizontal direction, wherein the horizontal direction is parallel to the upper surface of the second redistribution structure.

9. The semiconductor package of claim 8, wherein the conductive post includes a pillar portion and a connection layer disposed between the pillar portion and an upper surface of the first redistribution structure, and
wherein the pillar portion includes copper (Cu) and the connection layer includes lead (Pb).

10. The semiconductor package of claim 1, further comprising:
a connection member disposed between and directly contacts the bridge chip and the second redistribution structure.

11. A semiconductor package comprising:
a first redistribution structure;
a second redistribution structure disposed on the first redistribution structure;
a semiconductor chip disposed on an upper surface of the second redistribution structure;
a bridge chip disposed on a lower surface of the second redistribution structure;
a passive device disposed on the lower surface of the second redistribution structure and spaced apart from the bridge chip in a horizontal direction, wherein the horizontal direction is parallel to the upper surface of the second redistribution structure;
a molding layer disposed between the first redistribution structure and the second redistribution structure, wherein the molding layer surrounds the bridge chip and the passive device;
a conductive post spaced apart from the bridge chip and the passive device in the horizontal direction within the molding layer;
a heat sink disposed on an upper surface of the semiconductor chip; and
a stiffener disposed on the upper surface of the second redistribution structure, wherein the stiffener comprises an opening,
wherein the semiconductor chip is disposed in the opening of the stiffener.

12. The semiconductor package of claim 11, wherein the heat sink is spaced apart from an uppermost surface of the stiffener in a vertical direction, and
wherein the vertical direction is perpendicular to the horizontal direction.

13. The semiconductor package of claim 11, wherein the heat sink is in contact with an uppermost surface of the stiffener.

14. The semiconductor package of claim 11, wherein the heat sink includes a protrusion portion, and the protrusion portion protrudes toward the semiconductor chip.

15. The semiconductor package of claim 11, wherein a height of the passive device and a height of the bridge chip are different from each other.

16. A semiconductor package comprising:
a first redistribution structure comprising a passivation layer, an under bump metallurgy (UBM) layer disposed on and covering a portion of a lower surface of the passivation layer, and a conductive layer in contact with the UBM layer and exposed at an upper surface of the passivation layer;
a second redistribution structure disposed on the first redistribution structure, wherein the second redistribution structure comprises one or more redistribution insulating layers, one or more conductive line patterns disposed in the one or more redistribution insulating layers and extending in a horizontal direction, and one or more conductive vias disposed in the one or more redistribution insulating layers and extending in a vertical direction perpendicular to the horizontal direction, wherein the horizontal direction is parallel to an upper surface of the second redistribution structure;
one or more semiconductor chips disposed on the upper surface of the second redistribution structure;
a bridge chip disposed on a lower surface of the second redistribution structure, wherein the bridge chip provides an electrical connection path among the one or more semiconductor chips;
a passive device disposed on the lower surface of the second redistribution structure and spaced apart from the bridge chip in the horizontal direction;
a molding layer disposed between the first redistribution structure and the second redistribution structure, wherein the molding layer surrounds lower surfaces and side surfaces of the bridge chip and the passive device;
a conductive post spaced apart from the bridge chip and the passive device in the horizontal direction within the molding layer; and
a stiffener disposed on the upper surface of the second redistribution structure, wherein the stiffener comprises an opening,
wherein the one or more semiconductor chips are disposed in the opening of the stiffener.

17. The semiconductor package of claim 16, wherein a horizontal cross-section of the opening of the stiffener is a quadrangular shape.

18. The semiconductor package of claim 16, wherein an upper surface of the stiffener is at a lower vertical level than an upper surface of each of the one or more semiconductor chips.

19. The semiconductor package of claim 16, wherein the one or more semiconductor chips disposed in the opening of the stiffener are spaced apart from side walls of the opening of the stiffener by a gap ranging from about 2 mm to about 3 mm.

20. The semiconductor package of claim 16, further comprising:
a passive device connection member disposed between the passive device and the second redistribution structure; and
a bridge chip connection member disposed between the bridge chip and the second redistribution structure,
wherein each of the passive device connection member and the bridge chip connection member includes one or more of a solder ball and a conductive pillar.
